(19) United States
(12) Patent Application Publication
(10) Pub. No.: US 2015/0020882 A1
(43) Pub. Date: Jan. 22, 2015

(54) SEALING MEMBER AND SOLAR CELL INCLUDING THE SAME

(71) Applicant: SAMSUNG SDI CO., LTD., Yongin-si (KR)

(72) Inventors: Jong-Chul Lee, Yongin-si (KR); Chan-Yoon Jung, Yongin-si (KR); Yoon-Mook Kang, Yongin-si (KR); Yong-Mo Choi, Yongin-si (KR); Seung-Hee Lee, Yongin-si (KR); Jae-Hoon Lee, Yongin-si (KR); Do-Hyun Baek, Yongin-si (KR); Jong-San Im, Yongin-si (KR); Jeong-Ho Son, Yongin-si (KR); Sun-Dong Choi, Yongin-si (KR); Soon-Pil Hyeon, Yongin-si (KR); Bum-Rae Kim, Yongin-si (KR)

(73) Assignee: SAMSUNG SDI CO., LTD., Yongin-si (KR)

(21) Appl. No.: 14/079,562

(22) Filed: Nov. 13, 2013

Related U.S. Application Data
(60) Provisional application No. 61/847,965, filed on Jul. 18, 2013.

(51) Int. Cl. H01L 31/0203

(52) U.S. Cl. CPC H01L 31/0203
USPC 136/259

(57) ABSTRACT

A sealing member according to an exemplary embodiment of the present invention includes a first plate having a predetermined width with a plate shape, and a second plate with a plate shape connected to both ends of the first plate, wherein the first plate and the second plate have the same plate shape and form a closed line.

### CROSS-REFERENCE TO RELATED APPLICATION

This application claims priority to and the benefit of U.S. Provisional Application No. 61/847,965, filed on Jul. 18, 2013 in the U.S. Patent and Trademark Office, the entire content of which is incorporated herein by reference.

### BACKGROUND

1.Field

The present invention relates to a sealing member.

2.Description of the Related Art

A solar cell may be defined as an element converting light energy into electrical energy by using a photovoltaic effect in which an electron is generated if light is irradiated to a p-n junction diode. Based on the material used for the junction diode, solar cells may be divided into silicon solar cells, compound semiconductor solar cells using a group compound or a III-V group compound, dye response solar cells, and organic material solar cells.

Further, an organic light emitting diode display is a self-emitting type of display device having an organic light emitting diode and displaying an image.

This solar cell and this organic light emitting display device include a material that is vulnerable to moisture and oxygen such that cycle-life and reliability of the solar cell and the organic light emitting display device are reduced when they are exposed to moisture and oxygen.

Accordingly, to remove the moisture, in some cases a moisture absorbent material having one of various shapes is added before the sealing. However, typically the moisture is not completely prevented and the moisture penetrates inside the solar cell.

The above information disclosed in this Background section is only for enhancement of understanding of the background of the invention and therefore it may contain information that does not form the prior art that is already known in this country to a person of ordinary skill in the art.

### SUMMARY

Accordingly, the present invention provides a sealing member that substantially prevents penetration of moisture transmitting from the outside and a solar cell including the same.

A sealing member according to an exemplary embodiment of the present invention includes a first plate having a plate shape, and a second plate with a plate shape connected to both ends of the first plate, wherein the first plate and the second plate have the same plate shape and form a closed line.

A sealing member according to another exemplary embodiment of the present invention, to seal between a first substrate and a second substrate facing each other, wherein the sealing member includes a first sealing member bent at least once and contacting the first substrate and the second substrate with a plate shape, and a second sealing member surrounding the first sealing member and combining the first substrate and the second substrate.

In one embodiment, a solar cell includes a first substrate and a second substrate spaced from each other; a cell assembly comprising a first electrode on the first substrate; a first sealing member between the first and second substrates, and comprising a first portion contacting one of the first and second substrates and a second portion extending from the first portion such that first sealing member elastically supports the first and second substrates; and a second sealing member encompassing the first sealing member.

In an embodiment, the first sealing member further includes a third portion contacting another of the first and second substrates and the third portion may extend at an angle from the second portion and wherein the angles at which each of the first portion and the third portion extends from the second portion are identical to each other.

In various embodiments, each of the first and third portions extends substantially parallel to the first and second substrates, the first sealing member extends continuously around a periphery of the first and second substrates, and the second portion extends at an angle from the first portion, wherein the angle at which each of the second portion extends from the first portion is less than 90 degrees. Further, the first sealing member may be made from a waterproof material.

According to various embodiments, an end portion of the first portion may be curved away from the second portion, wherein a lateral cross-section of the second portion may be wave-shaped, at least one of the first portion may be arc-shaped, and the first sealing member may be generally S-shaped, generally Y-shaped, generally C-shaped, generally V-shaped, or generally M-shaped.

Additionally, the second portion may have a zig-zag shape, and the first sealing member may further include an assistance sealing member between the first portion and the first or second substrate. The assistance sealing member may be made of a butyl-based resin, an epoxy-based resin, a silicone-based resin, an adhesive, or double-sided tape.

In one embodiment, the second sealing member contacts both the first and second substrate and adheres the first substrate to the second substrate and a width of the first sealing member is less than a width of the second sealing member. Further, the first portion of the first sealing member may directly contact the first or second substrate and the compressibility of the first sealing member is less than an adhering force of the second sealing member to the first or second substrate.

According to an exemplary embodiment of the present invention, when the sealing member is formed as described above, the penetration of the moisture transmitted from the outside is prevented such that a solar cell with improved reliability may be provided.

### BRIEF DESCRIPTION OF THE DRAWINGS

FIG. 1 is a top plan view of a sealing member according to an exemplary embodiment of the present invention.

FIG. 2 is a cross-sectional view taken along the line II-II of FIG. 1.

FIG. 3 is a perspective view of a portion A of FIG. 1.

FIG. 4 is a top plan view of a sealing member according to another exemplary embodiment of the present invention.

FIG. 5 to FIG. 16 are cross-sectional views of a sealing member according to other exemplary embodiments of the present invention.

FIG. 17 is a schematic top plan view of a solar cell according to an exemplary embodiment of the present invention.

FIG. 18 is a cross-sectional view taken along the line XVI-XVI of FIG. 17.

FIG. 19 is a flowchart of a manufacturing method of a solar cell according to an exemplary embodiment of the present invention.

FIG. 20 is a schematic cross-sectional view of a solar cell according to another exemplary embodiment of the present invention.

### DETAILED DESCRIPTION

Hereinafter, exemplary embodiments of the present invention will be described in detail with reference to the attached drawings such that the present invention can be easily put into practice by those skilled in the art. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Now, an exemplary embodiment of the present invention will be described with reference to accompanying drawings.

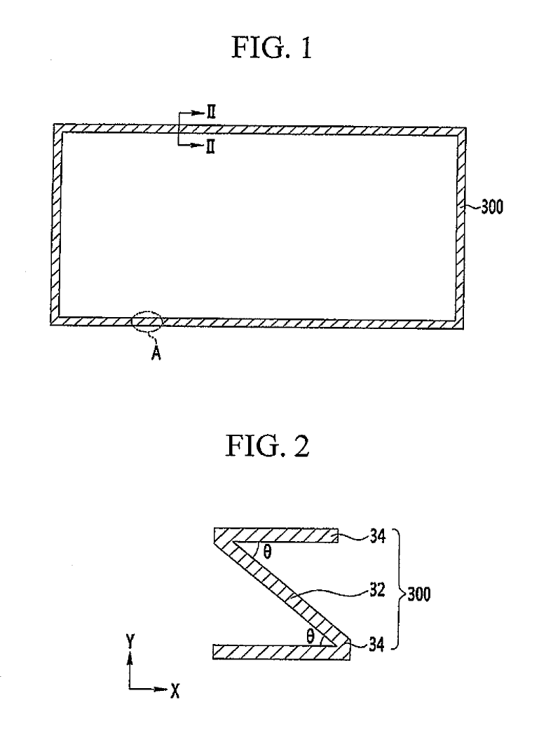

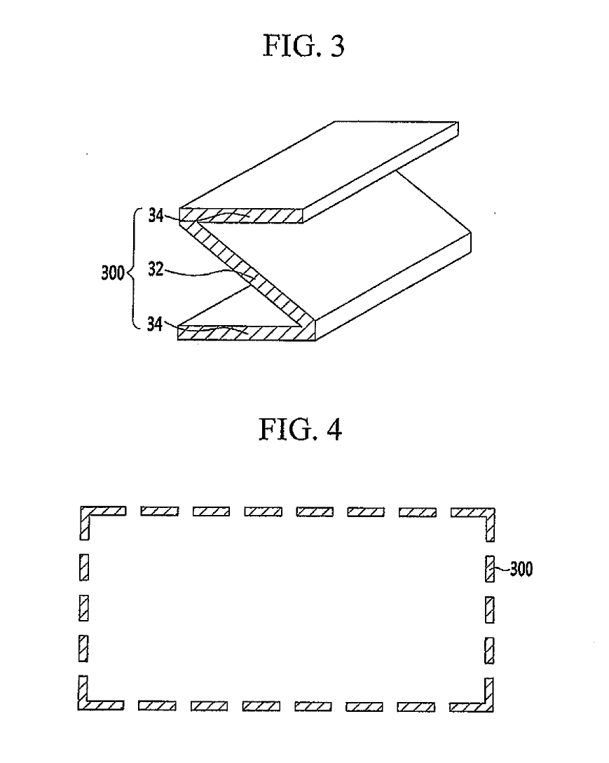

FIG. 1 is a top plan view of a sealing member according to an exemplary embodiment of the present invention, FIG. 2 is a cross-sectional view taken along the line II-II of FIG. 1, FIG. 3 is a perspective view of a portion A of FIG. 1, and FIG. 4 is a top plan view of a sealing member according to another exemplary embodiment of the present invention.

The sealing member 300 may have a flat shape that is bent at least once. The sealing member 300 may be formed of any material having a waterproof function and elasticity (i.e. the material can be folded into a shape having elastic properties as described in more detail below), for example, stainless steel, corrosion resistance copper alloys, corrosion resistance aluminum alloys, and corrosion resistance nickel alloys.

The sealing member 300 includes a first plate 32 having a plate shape, and second plates 34 connected to respective ends of the first plate 32 and having a plate shape. Each second plate 34 is connected with an angle θ less than 90 degrees with respect to the first plate 32. The second plates 34 positioned at respective sides with respect to the first plate 32 may be parallel to each other.

As shown in FIG. 1, the sealing member 300 may form an integrally closed shape (i.e., the sealing member may be entirely continuous) and may be formed by forming a pair of transverse portions and a pair of longitudinal portions and then connecting both ends thereof by welding.

As shown in FIG. 4, a plurality of sealing members 300 may be formed and disposed at or proximate to an edge of the substrate. When forming a plurality of sealing members 30 like this, moisture may penetrate a region enclosed by the sealing members through spaces between the sealing members such that a liquefied sealing member filling between the sealing members 300 may be necessary.

If the sealing member 300 is formed as in the present invention, when applying a force to the second plate 34 in a Y-axis direction, the sealing member 300 contracts like a spring and then tends to rebound to an original state by elastic force. If the second plate 34 and the first plate 32 are connected at a 90 angle, when an external force is applied to the second plate 34, it is more difficult for the first plate 32 to be bent in any direction such that the elastic force is not generated.

In the present invention, when forming the sealing member 300 of the plate shape while having the elastic force, moisture penetration from the outside may be easily prevented. In other words, if the sealing member 300 is positioned between two substrates, the sealing member 300 and the two substrates come into close contact with each other by the elastic force such that the external moisture does not pass between the second plate and the substrate and does not pass through the first plate 32 so it does not penetrate inside. The inside is therefore completely surrounded by the sealing member.

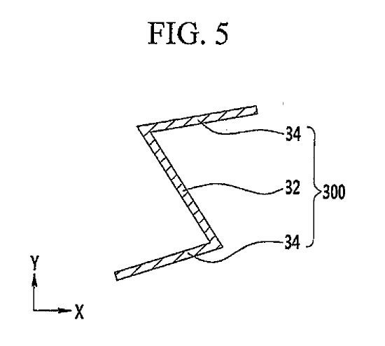

The sealing member according to the present invention may be formed with various shapes as shown in FIG. 5 to FIG. 16.

FIG. 5 to FIG. 16 are cross-sectional views of sealing members according to other exemplary embodiments of the present invention.

The sealing members of FIG. 5 to FIG. 16 are sealing members of FIGS. 1 to 4 such that the cross-sectional of the sealing member is focused on hereafter.

As shown in FIG. 5, the sealing member 30 may be inclined with respect to the X-axis or the Y-axis. In this embodiment, the angle at which the second plate 34 is inclined with respect to the X-axis may be smaller than the angle at which the second plate 34 is inclined with respect to the Y-axis.

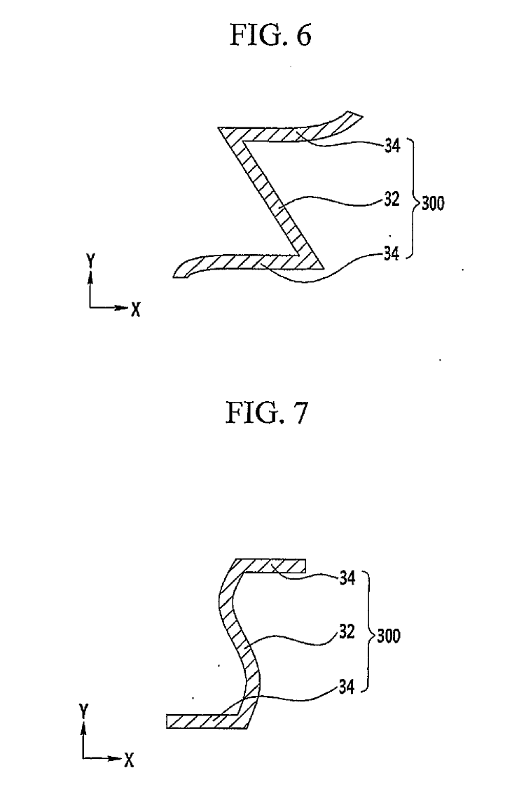

As shown in FIG. 6, the second plates 34 of the sealing member 300 are parallel to each other and may be bent in the Y-axis direction.

The sealing member 300 may be bent such that the first plate 32 may form a smooth curved line as shown in FIG. 7. In this embodiment, the second plates 34 are parallel to each other and parallel to the X-axis. Of course, the second plate 34 of the sealing member 300 of FIG. 6 may also be inclined with respect to the X-axis as shown in FIG. 5 and FIG. 6, and may be bent in the Y-axis direction.

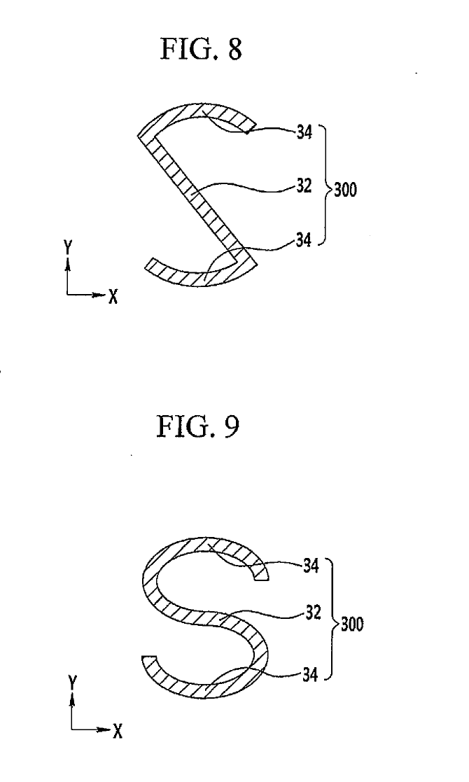

As shown in FIG. 8, the sealing member 300 is bent such that the second plate 34 forms a smooth curved line thereby protruding in the Y-axis direction.

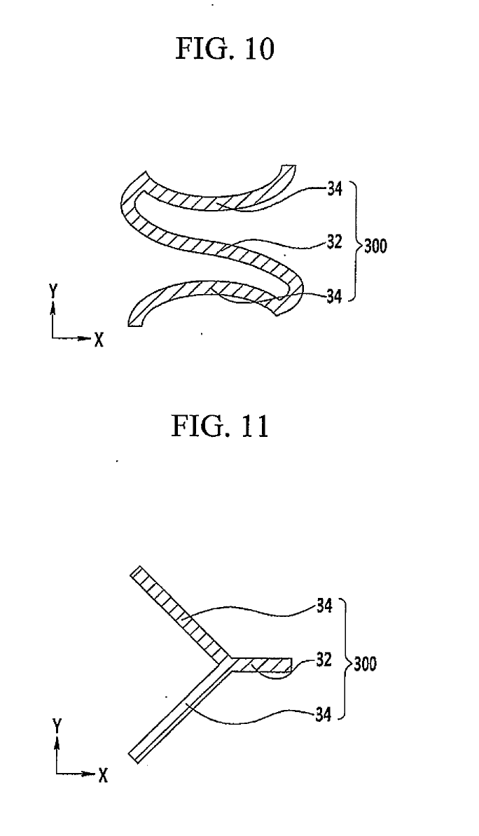

Also, the sealing member 300 may be formed such that the first plate 32 and the second plate 34 are curved, as shown in FIG. 9. In the exemplary embodiment of FIGS. 8 and 9, the second plates 34 are formed to protrude in opposite directions, however, as shown in FIG. 10, the protruded portions may be formed to face each other.

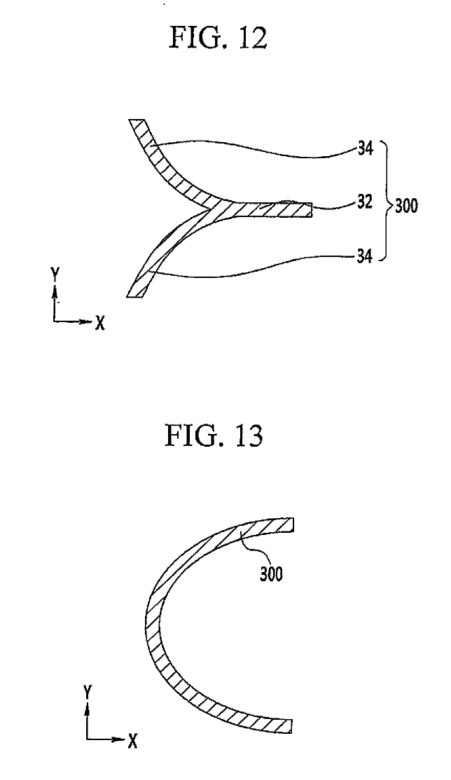

As shown in FIG. 11 and FIG. 12, the sealing member 300 includes the first plate 32 and a pair of the second plates 34 divided from one end of the first plate 32 and extending in the Y-axis and the −Y-axis directions. As shown in FIG. 12, the second plates 34 may be bent in a curved configuration.

The sealing member 300 of FIG. 11 and FIG. 12 may be formed by bending or curving one plate to form a pair of second plates and by connecting a first plate to a bent portion of the second plates.

Also, two plates may be provided, and may be bent or curved to have the first and the second plates and the first plates may be connected to each other to form the sealing member 300.

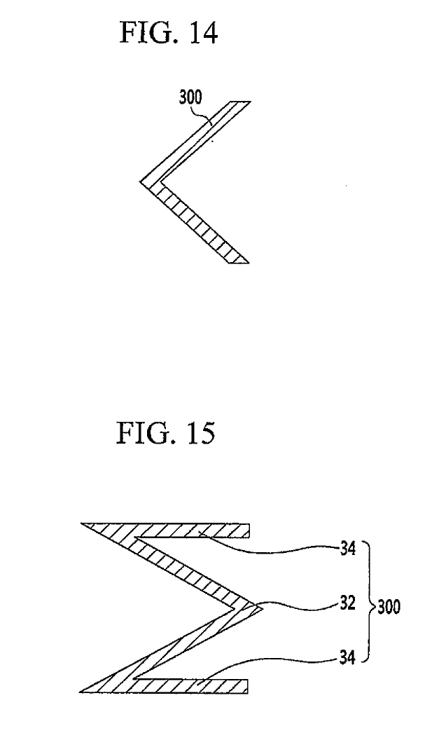

As shown in FIG. 13, the sealing member may be made of one plate and may be bent one time as shown FIG. 14 to have a V formation.

As shown in FIG. 15, the first plate 32 is bent such that the sealing member 300 may have a zigzag shape or a sideways M shape. In FIG. 15, the first plate 32 is bent once, however it may be bent multiple times. As shown in FIG. 15, if it is formed with the zigzag shape, the number of bent portions is increased such that the elastic force is increased.

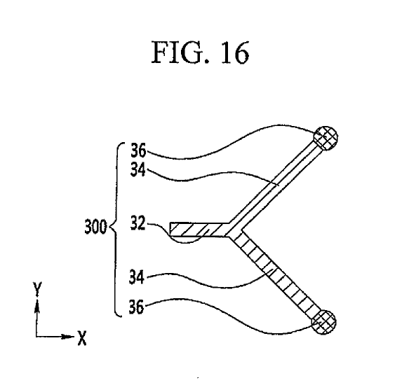

As shown in FIG. 16, in the sealing member 300, an assistance sealing member 36 may be formed at an end of the second plate 34. The assistance sealing member 36 may include a material having elasticity and an excellent contacting force, for example, a butyl-based resin, an epoxy-based resin, or a silicon-based resin. Also, the assistance sealing member 36 may be formed of a material having an adhesiveness.

Accordingly, when the sealing member 300 is positioned between two substrates and the end of the second plate contacts the surface of the substrate for sealing the two substrates, the contact area between the second plate and the surface of the substrate is increased such that a sealing force may be increased. In other words, if the second plate is formed parallel to the X-axis, the second plate and the substrate surface are surface-contacted, however if the second plate is inclined with respect to the X-axis, the end of the second plate contacts the substrate surface such that the contact area is reduced. Accordingly, if the assistance sealing member is formed, the contact area of the substrate surface of the sealing member is increased such that the sealing force may be improved.

The assistance sealing member of FIG. 16 is formed at the sealing member of FIG. 11, however it may be formed at one end of all sealing members of FIG. 1 to FIG. 15.

In the above exemplary embodiment, the first plate 32 and the second plate 34 are divided, however the first plate 32 and the second plate 34 may be formed of one plate to be bent at least once. Of course, an additional plate may be connected by welding.

Next, as shown in FIG. 1 to FIG. 16, the solar cell including the sealing member according to the present invention and a manufacturing method thereof will be described.

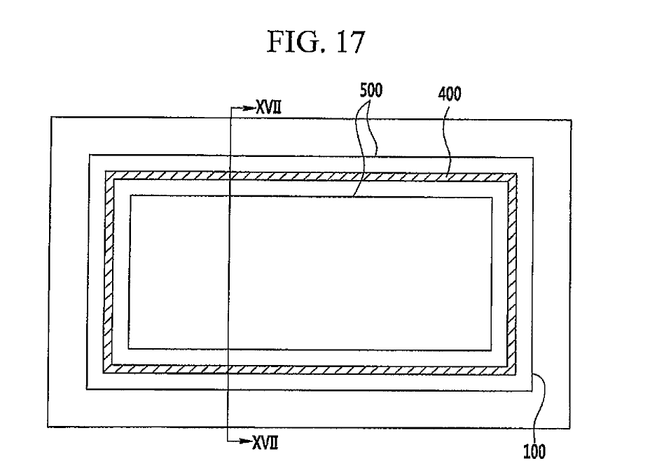

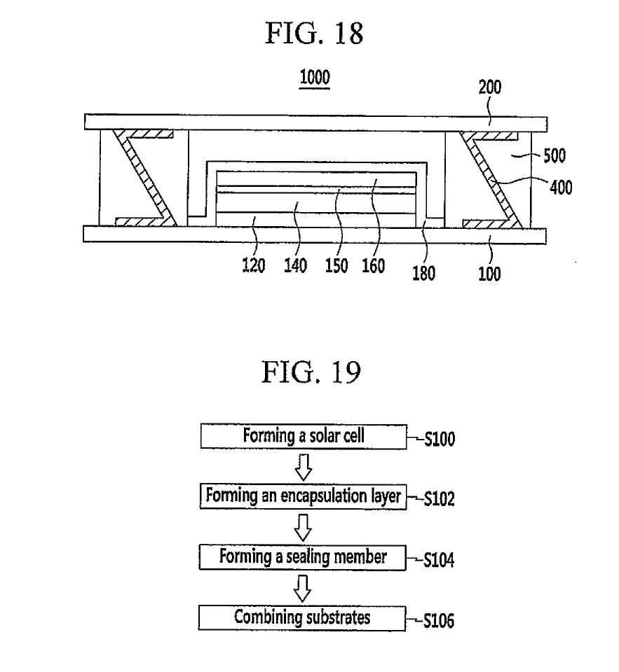

FIG. 17 is a schematic top plan view of a solar cell according to an exemplary embodiment of the present invention, and FIG. 18 is a cross-sectional view taken along the line XVIII-XVIII of FIG. 17.

As shown in FIG. 17 and FIG. 18, the solar cell 1000 according to the present invention includes a first substrate 100 and a second substrate 200 facing each other, a first sealing member 400 and a second sealing member 500 sealing between the first substrate 100 and the second substrate 200, and a solar cell positioned between the two sealed substrates and formed on the first substrate 100.

The substrate 100 has an insulating characteristic and may be made of a transparent material such as a soda lime glass. The substrate 100 may include a large amount of sodium (Na).

As shown in FIG. 18, the solar cell includes a first electrode 120 formed on the substrate 100, a photoactive layer 140 formed on the first electrode 120, a buffer layer 150 formed on the photoactive layer, a second electrode 160 formed on the buffer layer 150, and an encapsulation layer 180 formed on the second electrode 160.

In one embodiment, the solar cell is formed of a plurality of unit cells that may be coupled in series or in parallel.

The first electrode 120 may be formed of a metal having a heat-resistant characteristic, an excellent electrical contact characteristic with the material forming the photoactive layer, excellent electrical conductivity, and excellent interface cohesion with the substrate 100, for example, molybdenum (Mo).

The photoactive layer 140 as a P type CIS-based semiconductor may include selenium (Se) or sulfur (S). For example, the photoactive layer 140 as a I-III-VI-based semiconductor compound may be Cu(In₁₋ₓ,Gaₓ)(Se₁₋ₓ,Sₓ), and may be a compound semiconductor having a composition wherein 0≦x≦1. The photoactive layer 140 may have a single phase in which the composition of the compound semiconductor is substantially uniform. For example, it may be CuInSe₂, CuInS₂, Cu(In,Ga)Se₂, (Ag,Cu)(In,Ga)Se₂, (Ag,Cu)(In,Ga)(Se,S)₂, Cu(In,Ga)(Se,S)₂, or Cu(In,Ga)S₂. Also, the photoactive layer 140 may include sodium (Na) diffused from the substrate 100.

The buffer layer 150 smoothes an energy gap difference between the photoactive layer 140 and the second electrode 150. The buffer layer 150 may be formed of an n-type semiconductor material having high light transmittance, for example, CdS, ZnS, or InS.

The second electrode 160 may be formed of a material having high light transmittance and excellent electrical conductivity, for example, ZnO, and the light transmittance may be more than about 80%. Also, the ZnO layer is doped with aluminum (Al) or boron (B) thereby having low resistance.

Also, an ITO layer having excellent electrical and light transmittance characteristics may be deposited on the ZnO layer, and the second electrode 160 may be formed of the ITO single layer. Also, an n-type ZnO layer having low resistance may be formed on an i-type ZnO layer that is not doped.

The second electrode 160 as the n-type semiconductor forms a pn junction along with the photoactive layer as the p-type semiconductor.

The encapsulation layer 180 may be formed of a material preventing the moisture and oxygen penetrating, for example, EVA (ethylene vinyl acetate).

The first sealing member 400 may be one among the sealing members of the plate shape having the elastic force shown in FIG. 1 to FIG. 16, and an example of the sealing member of FIG. 2 is described in FIG. 18.

The second plate 34 of the first sealing member 400 is parallel to the first substrate surface and the second substrate surface, and one surface of the second plate 34 and the first substrate surface or the second substrate surface contact each other. When using the sealing member of FIG. 4 to FIG. 14 as the first sealing member, the second plates 34 also contact the first substrate surface and the second substrate surface.

The second sealing member 500 is linearly formed according to the edge of the substrate 100 thereby forming an enclosed curved line. The second sealing member 500 has adherence and contacts the first substrate 100 and the second substrate 200 thereby combining the two substrates. The second sealing member 500 may include a material to be sealed by using visible rays or heat, for example, a butyl-based resin, an epoxy-based resin, or a silicon-based resin.

The plane shapes of the first sealing member 400 and the second sealing member 500 are the same, and the first sealing member 400 is positioned within the boundary of the second sealing member 500. In other words, the first sealing member 400 is narrower than the second sealing member 500, and the second sealing member 500 fills the space between the first plate 32 and the second plate 34 of the first sealing member 400 and encloses the first sealing member 400.

The first sealing member 400 has elastic force without the adherence such that it does not combine the two substrates, such that the width of the second sealing member 500 is larger than the width of the first sealing member 400 to contact the two substrates for the combination.

In one embodiment, as shown in FIG. 16, if the assistance sealing member 36 is included and the first sealing member 400 including the assistance sealing member 36 formed of the material having an adhesiveness is formed, a width of the second sealing member 500 may be reduced or the second sealing member 500 may be omitted.

The second substrate 200 to protect the solar cell from physical impacts and foreign materials from the outside may be a tempered glass.

In an exemplary embodiment of the present invention, when forming the first sealing member 400 and the second sealing member 500, the penetration of external moisture to the solar cell positioned between the two substrates may be prevented. In other words, by the elastic force of the first sealing member 400, the second plates of the first sealing member closely contact the first substrate surface and the second substrate surface. Accordingly, a moisture moving path is eliminated between the first sealing member and the substrate so the external moisture may not move to the inside where the solar cell is positioned.

In one embodiment, the second sealing member 500 has strong adherence such that the first substrate 100 and the second substrate 200 are not separated. Accordingly, the elastic force of the first sealing member 400 must be smaller than the adherence of the second sealing member 500 such that the first substrate 100 and the second substrate 200 may be not separated by the elastic force of the first sealing member 400.

The adherence of the second sealing member 500 may be reduced, for example, to 1/10 compared with initial adherence such that the elastic force of the first sealing member 400 with respect to that of the second sealing member 500 is preferably less than 1/10 of the adherence by considering the reduced adherence.

Next, a method of forming the solar cell of FIG. 17 and FIG. 18 will be described with reference to FIG. 19 as well as FIG. 18.

FIG. 19 is a flowchart of a manufacturing method of a solar cell according to an exemplary embodiment of the present invention.

As shown in FIG. 19, the method includes providing the first substrate and forming a solar cell on the first substrate (S100), forming an encapsulation layer on the solar cell (S102), forming a sealing member on the first substrate (S104), and aligning and combining the second substrate (S106).

In the forming of the solar cell on the first substrate (S100), the solar cell shown in FIG. 18 may be manufactured by any well-known general method, and a deposition structure thereof is not limited thereto.

In the forming of the encapsulation layer on the solar cell (S102), the encapsulation layer covers the entire solar cell and may be made of the EVA.

In the forming of the sealing member on the first substrate (S104), the second sealing member in a solution state is coated according to the edge of the first substrate to enclose the solar cell on the first substrate 100.

The first sealing member 400 is also located on the second sealing member 500. The first sealing member 400 may one among the sealing members shown in FIG. 1 to FIG. 14.

In one embodiment, the second sealing member 500 may be formed by only one coating to sufficiently enclose the first sealing member 400, but it may also be coated twice. After forming the second sealing member 500 by coating once, if the first sealing member 400 is provided, a pressing process is required to completely insert the second sealing member 500 inside the first sealing member 400.

However, if the second sealing member 500 is coated twice, the pressing process to insert the first sealing member 400 may be omitted.

In other words, if a portion of the entire required amount of the second sealing member 500 is coated and then the first sealing member 400 is disposed, a thickness of the second sealing member 500 is not high such that the first sealing member 400 may be inserted to the second sealing member 500. Also, even if the first sealing member 400 is not inserted, the rest of the second sealing member 500 is coated on the first sealing member 400 such that the second sealing member 500 may be formed to completely enclose the first sealing member 400.

Although the second sealing member 500 is coated on the first sealing member 400, the second sealing member 500 positioned between the substrate surface and the second plate is pushed out by the later pressing process such that the second plate of the first sealing member 400 and the substrate surface may fully contact.

In the aligning and combining of the second substrate 200 (S106), the second substrate 200 is disposed and aligned on the sealing member 400 and 500 to face the first substrate.

Next, the second substrate 200 is pressed to contact the first sealing member 400 with the first substrate 100 and the second substrate 200, and then the first substrate 100 and the second substrate 200 are completely sealed by hardening the first sealing member 400 thereby completing the solar cell.

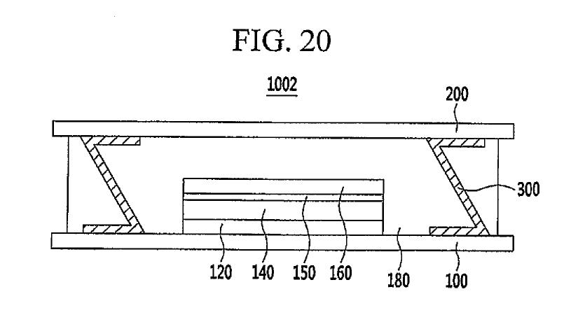

FIG. 20 is a schematic cross-sectional view of a solar cell according to another exemplary embodiment of the present invention.

Most of the interlayer configuration is equivalent to that described with reference to FIG. 17 and FIG. 18, so no repeated description will be provided.

A solar cell 1002 of FIG. 20 includes the first substrate 100 and the second substrate 200 facing to each other, the sealing member 300 sealing the space between the first substrate 100 and the second substrate 200, and cells positioned between the first substrate 100 and the second substrate 200 and formed on the first substrate 100.

In the solar cell of FIG. 20, the encapsulation layer 180 extends to a peripheral area (or an edge of the substrate of the solar cell) as well as an area where the cells are positioned, and the second substrate 200 is contacted with the encapsulation layer 180. Accordingly, if the encapsulation layer 180 extends to the peripheral area, the second sealing member may be omitted differently from FIG. 18. In other words, the encapsulation layer 180 of the solar cell extends to the peripheral area of the cells, and one sealing member among FIG. 1 to FIG. 16 is disposed, the second substrate 200 is aligned and thermo-compressed, and then the sealing member is hardened for sealing.

In the above exemplary embodiment, the solar cell is described as an example, however any organic light emitting display device including the organic light-emitting device may be sealed by using the sealing member like an exemplary embodiment of the present invention. That is, the organic light emitting display device includes the organic light-emitting device positioned on the substrate and forming a matrix, a plurality of signal lines connected to the organic light emitting light-emitting device, and thin film transistors. The sealing member is formed on the substrate and protects the organic light emitting light-emitting device along with an opposing substrate from external moisture.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

Description of Symbols

| | |
|---|---|
| 32: first plate | 34: second plate |
| 36: assistance sealing member | 100: first substrate |
| 120: first electrode | 140: photoactive |
| 150: buffer layer | 160: second electrode |
| 180: encapsulation layer | 200: second substrate |

| | |
|---|---|
| 300: sealing member | 400: first sealing member |
| 500: second sealing member | 1000: solar cell |

What is claimed is:

1. A solar cell comprising:
a first substrate and a second substrate spaced from each other;
a cell assembly comprising a first electrode on the first substrate;
a first sealing member between the first and second substrates, and comprising a first portion contacting one of the first and second substrates and a second portion extending from the first portion such that first sealing member elastically supports the first and second substrates; and
a second sealing member encompassing the first sealing member.

2. The solar cell of claim 1, wherein the first sealing member further comprises a third portion contacting another of the first and second substrates.

3. The solar cell of claim 2, wherein the third portion extends at an angle from the second portion and wherein the angles at which each of the first portion and the third portion extends from the second portion are identical to each other.

4. The solar cell of claim 2, wherein each of the first and third portions extends substantially parallel to the first and second substrates.

5. The solar cell of claim 1, wherein the first sealing member extends continuously around a periphery of the first and second substrates.

6. The solar cell of claim 1, wherein the second portion extends at an angle from the first portion, and wherein the angle at which each of the second portion extends from the first portion is less than 90 degrees.

7. The solar cell of claim 1, wherein the first sealing member comprises a waterproof material.

8. The solar cell of claim 1, wherein the first sealing member comprises stainless steel, a corrosion resistant copper alloy, a corrosion resistant aluminum alloy, or a corrosion resistant nickel alloy.

9. The solar cell of claim 1, wherein an end portion of the first portion is curved away from the second portion.

10. The solar cell of claim 1, wherein a lateral cross-section of the second portion is wave-shaped.

11. The solar cell of claim 1, wherein at least one of the first portion is arc-shaped.

12. The solar cell of claim 1, wherein the first sealing member is generally S-shaped, generally Y-shaped, generally C-shaped, generally V-shaped, or generally M-shaped.

13. The solar cell of claim 1, wherein the second portion has a zig-zag shape.

14. The solar cell of claim 1, wherein the first sealing member further comprises an assistance sealing member between the first portion and the first or second substrate.

15. The solar cell of claim 14, wherein the assistance sealing member comprises a butyl-based resin, an epoxy-based resin, a silicone-based resin, an adhesive, or double-sided tape.

16. The solar cell of claim 1, wherein the second sealing member contacts both the first and second substrate and adheres the first substrate to the second substrate.

17. The solar cell of claim 1, wherein a width of the first sealing member is less than a width of the second sealing member.

18. The solar cell of claim 1, wherein the second sealing member comprises a butyl-based resin, an epoxy-based resin, or a silicone-based resin.

19. The solar cell of claim 1, wherein the first portion of the first sealing member directly contacts the first or second substrate.

20. The solar cell of claim 1, wherein the compressibility of the first sealing member is less than an adhering force of the second sealing member to the first or second substrate.
